(19) United States
(12) Patent Application Publication
(10) Pub. No.: US 2016/0014366 A1
(43) Pub. Date: Jan. 14, 2016

(54) EXTENDED DYNAMIC RANGE CHARGE TRANSIMPEDANCE AMPLIFIER INPUT CELL FOR LIGHT SENSOR

(71) Applicant: Raytheon Company, Waltham, MA (US)

(72) Inventors: David Chiaverini, Irvine, CA (US); John L. Vampola, Santa Barbara, CA (US); Micky Harris, Lompoc, CA (US)

(21) Appl. No.: 14/325,744

(22) Filed: Jul. 8, 2014

(51) Int. Cl. H04N 5/3745; H04N 3/14; H04N 5/235

(52) U.S. Cl. CPC H04N 5/37457; H04N 5/2355; H04N 3/1556; H04N 5/37452

(57) ABSTRACT

A charge transimpedance amplifier (CTIA) input cell includes a high gain capacitor configured to integrate charge arising from photocurrent, a low gain capacitor, and a switching element that can switch the low gain capacitor to be electrically coupled in parallel to the high gain capacitor. In some examples, the switching element is a low gain switch, which can be manually activated to switch in the low gain capacitor. In these examples, the low gain switch can be electrically disposed between the low gain capacitor and a source of the photocurrent. In other examples, the switching element is a low gain transistor, which can be automatically activated to switch in the low gain capacitor when a voltage across the high gain capacitor reaches a specified threshold. In these examples, the low gain capacitor can be electrically disposed between the low gain transistor and the source of the photocurrent.

### TECHNICAL FIELD

Examples relate to a charge transimpedance amplifier (CTIA) unit cell for a light sensor, capable of automatically, and effectively, accommodating relatively low and relatively high light levels.

### BACKGROUND

Circuitry for a light sensor is often designed to effectively accommodate a relatively low light level or a relatively high light level, but not both. A circuit designed for a relatively low light level can saturate when used at a relatively high light level. A circuit designed for a relatively high light level can have noise that overwhelms the signal when used at a relatively low light level.

Accordingly, there exists a need for circuitry for a light sensor that can automatically, and effectively, accommodate both relatively low and high light levels.

### BRIEF DESCRIPTION OF THE DRAWINGS

FIG. 1 is a functional diagram of an example of an image capture device in accordance with some embodiments.

FIG. 2 is an electrical schematic drawing of an example of a CTIA input cell in accordance with some embodiments.

FIG. 3 includes plots of examples of a reset signal and output voltages for the CTIA input cell of FIG. 2, in accordance with some embodiments.

FIG. 4 is an electrical schematic drawing of an example of a CTIA input cell, in which a summed capacitance can be varied manually, in accordance with some embodiments.

FIG. 5 is an electrical schematic drawing of an example of a CTIA input cell, in which a summed capacitance can be varied automatically, in accordance with some embodiments.

FIG. 6 includes plots of examples of a reset signal and output voltages for the CTIA input cell of FIG. 5, in accordance with some embodiments.

FIG. 7 is an electrical schematic drawing of an example of a CTIA input cell, used with a rolling shutter configuration for the image capture device, in accordance with some embodiments.

FIG. 8 is an electrical schematic drawing of an example of a CTIA input cell, used with a serial snapshot configuration for the image capture device, in accordance with some embodiments.

FIG. 9 is an electrical schematic drawing of an example of a CTIA input cell, used with a one output parallel snapshot configuration for the image capture device, in accordance with some embodiments.

FIG. 10 is an electrical schematic drawing of an example of a CTIA input cell, used with a two output parallel snapshot configuration for the image capture device, in accordance with some embodiments.

FIG. 11 is a flow chart of an example of a method of operation for a CTIA input cell, in accordance with some embodiments.

FIG. 12 is a flow chart of another example of a method of operation for a CTIA input cell, in accordance with some embodiments.

### SUMMARY

A charge transimpedance amplifier (CTIA) input cell includes a high gain capacitor configured to integrate charge arising from photocurrent, a low gain capacitor, and a switching element that can switch the low gain capacitor to be electrically coupled in parallel to the high gain capacitor. In some examples, the switching element is a low gain switch, which can be manually activated to switch in the low gain capacitor. In these examples, the low gain switch can be electrically disposed between the low gain capacitor and a source of the photocurrent. In other examples, the switching element is a low gain transistor, which can be automatically activated to switch in the low gain capacitor when a voltage across the high gain capacitor reaches a specified threshold. In these examples, the low gain capacitor can be electrically disposed between the low gain transistor and the source of the photocurrent. The CTIA can be single-sided or can be differential.

### DETAILED DESCRIPTION

The following description and the drawings sufficiently illustrate specific embodiments to enable those skilled in the art to practice them. Other embodiments can incorporate structural, logical, electrical, process, and other changes. Portions and features of some embodiments can be included in, or substituted for, those of other embodiments. Embodiments set forth in the claims encompass all available equivalents of those claims.

There are many types of image capturing devices such as digital cameras, video cameras, and other photographic and/or image capturing devices. These image capturing devices can use image sensors such as active pixel sensors (APS), arrays of photodiodes, or other suitable light sensing devices in order to capture an image. For example, an APS can include an array of unit cells that receives light from a lens. Each unit cell in the array generally corresponds to the smallest portion of a digital image, known as a pixel. The light causes each unit cell to accumulate an electric charge proportional to the light intensity at that location. Circuitry and/or software in the image capturing device then interprets the charge accumulated in the unit cell to produce the corresponding pixel of the final image.

Typically, each unit cell in the array includes a component to store the electric charge until it can be read and analyzed. In some unit cells, this component can be an integration capacitor. The size of the integration capacitor can vary according to the specific application of the imaging device, and is usually selected to accommodate the greatest amount of electric charge expected to be encountered for the application.

Image capturing devices are routinely exposed to both low ambient and high ambient light situations. As a result, it is desirable for an image capturing device to have a high dynamic range, e.g., the ability to perform well in both low ambient and high ambient light situations. In a low ambient light situation such as pictures taken at night, indoors, in shadows, or other situations where there is a relatively low amount of ambient light, the electric charge accumulated in the unit cell will be relatively low. As a result, a relatively small amount of capacitance is needed to store electric charge in low ambient light situations and therefore a relatively small integration capacitor can be desired. Conversely, in high ambient light situations such as a sunny day, a well-lit room, or other situations where there is a relatively large amount of ambient light, the electric charge accumulated in the unit cell will be relatively high due to the greater intensity of the light captured by the image capture device. As a result, a relatively large amount of capacitance is needed to store electric charge in high ambient light situations and therefore a relatively large integration capacitor can be needed.

As mentioned above, most integration capacitors are chosen to accommodate the greatest amount of electric charge expected to be encountered for a specific application. Because of this, integration capacitors tend to be relatively large in size so that they will not saturate and cause a loss of information. This works well for high ambient light situations which generate larger amounts of electric charge, but is less desirable in low ambient light situations where there is a relatively small amount of electric charge to store. In low ambient light situations, there will be a relatively low signal-to-noise ratio due to the lower electric charge. To combat the low signal-to-noise ratio in these situations, a relatively small integration capacitor is more desirable. This creates a dichotomy for unit cell designers: choose a small integration capacitor that will perform well in low ambient light situations but can easily saturate in high ambient light situations, or choose a larger integration capacitor that will not saturate in high ambient light situations but will perform poorer in low ambient light situations.

Additionally, in order to capture an image, most image capturing devices having an integration capacitor must reset the integration capacitor through a switch prior to capturing the image. This reset involves applying a voltage V to both sides of the integration capacitor, so that the voltage across the integration capacitor is set to zero volts. In reality, however, the voltage measured across the integration capacitor after this reset will not be exactly zero volts, but rather will be zero volts plus or minus some small amount of error. This error is known as kTC noise, or reset noise. The effects of kTC noise become significant at relatively low light levels, at which the signal is relatively small.

Accordingly, it would be desirable for a unit cell to perform optimally in both low ambient and high ambient light situations (e.g., to have a high dynamic range) while providing a low kTC reset noise.

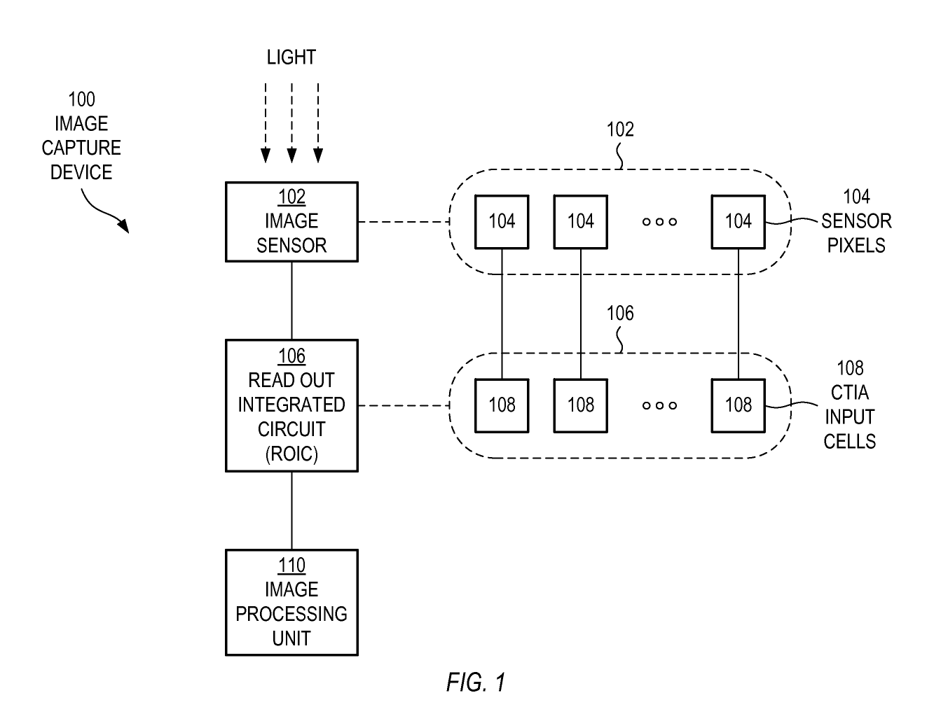

FIG. 1 is a block diagram illustrating an image capture device 100 that can be used to capture images. For example, device 100 can be a digital camera, video camera, or any other photographic and/or image capturing device. Image capture device 100 includes image sensor 102, read out integrated circuit (ROIC) 106, and image processing unit 110.

Image sensor 102 can be an APS, an array of photodiodes, or any other suitable light sensing device that can capture images. Image sensor 102 can include, for example, a diode, a charge-coupled device (CCD), or any other photovoltaic detector or transducer. Image sensor 102 senses a scene as an array of pixels 104, where each pixel receives light from a corresponding portion of an imaged scene, and produces current in response to the received light.

A read out integrated circuit (ROIC) 106 includes a plurality of charge transimpedance amplifier (CTIA) input cells 108, with each CTIA input cell corresponding to a sensor pixel 104. Each CTIA input cell 108 receives a photocurrent generated by the corresponding sensor pixel 104, integrates the photocurrent for a particular frame duration as a stored charge, and outputs a particular voltage at the end of the frame, the voltage corresponding to the stored charge. The CTIA input cells 108 all work in parallel, with the ROIC 106 assembling and correlating the output voltages from the CTIA input cells 108. Other types of input cells can also be used, including source/follower, direct injection, buffered direct injection, and others.

An image processing unit 110 can convert the assembled and correlated information from the ROIC 106 into an electronic representation of the image incident on the image sensor 102.

Image processing unit 110 can be a combination of hardware, software, or firmware that is operable to receive signal information from the ROIC 106 and convert the signal information into an electronic image. Examples can also be implemented as instructions stored on a computer-readable storage device, which can be read and executed by at least one processor to perform the operations described herein. A computer-readable storage device can include any non-transitory mechanism for storing information in a form readable by a machine (e.g., a computer). For example, a computer-readable storage device can include read-only memory (ROM), random-access memory (RAM), magnetic disk storage media, optical storage media, flash-memory devices, and other storage devices and media. In some examples, computer systems can include one or more processors, optionally connected to a network, and can be configured with instructions stored on a computer-readable storage device.

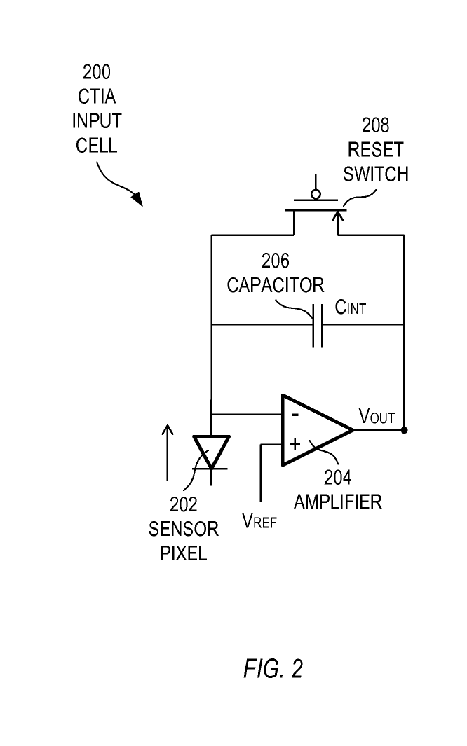

FIG. 2 is an electrical schematic drawing of an example of a CTIA input cell 200. The CTIA input cell 200 receives photocurrent generated by sensor pixel 202. The output from the sensor pixel 202 is electrically coupled to an input to amplifier 204, to a first side of an integration capacitor 206 having capacitance C_{INT}, and a first side of reset switch 208. Amplifier 204 has a constant voltage V_{REF} as its other input, and a variable voltage V_{OUT} as its output. The amplifier output is electrically coupled to a second side of the integration capacitor 206, and to a second side of reset switch 208. The amplifier output V_{OUT} also forms the output voltage from the known CTIA input cell 200. The ROIC periodically opens the reset switch 208 to start each video frame, and closes the reset switch 208 briefly to end each video frame. Closing the reset switch 208 resets the voltage across the integration capacitor 206 to zero volts, plus or minus kTC noise.

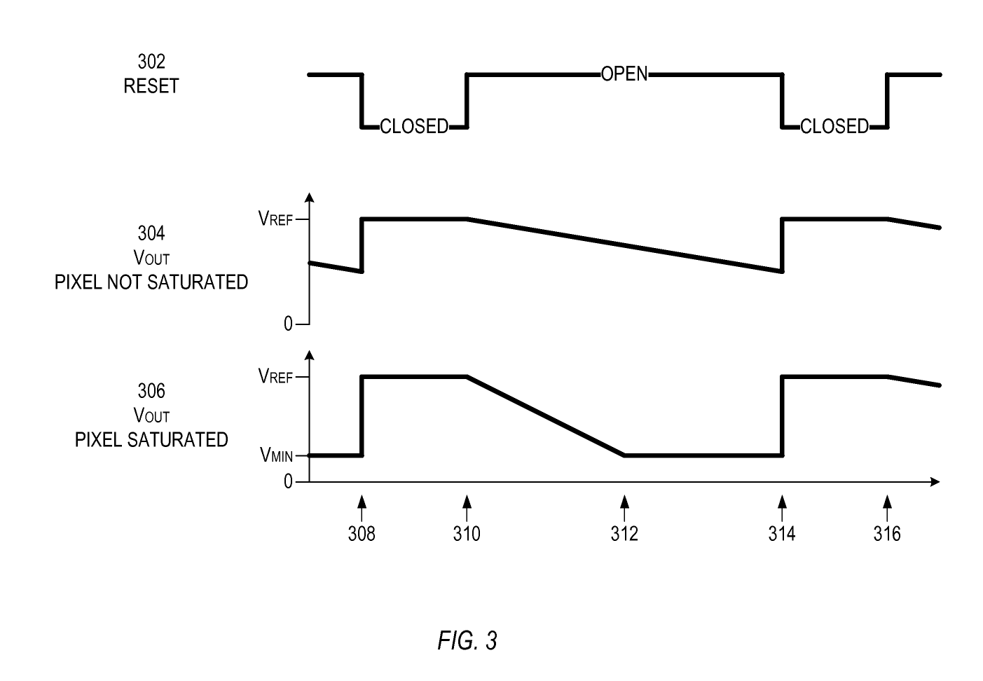

FIG. 3 includes plots of examples of a reset signal 302 and output voltages for the CTIA input cell of FIG. 2, for a particular sensor pixel. The reset switch closes at time 308, opens at time 310, closes at time 314, and opens at time 316.

Plot 304 shows the output voltage V_{OUT} when the light intensity striking the sensor pixel is relatively low. When the reset switch closes, the capacitor is set to a reset voltage V_{REF}. When the reset switch opens, the capacitor begins receiving charge from the photocurrent. The charge is said to integrate on the capacitor (206; FIG. 2). As the charge integrated on the capacitor increases, the voltage across the capacitor drops from its initial voltage V_{OUT}. The frame ends at time 314, before the dropping voltage reaches zero. A sample and hold element (not shown in FIG. 2) can record the output voltage just prior to the end of the frame. The output voltage corresponds to a particular light intensity at the sensor pixel, averaged over a frame.

Plot 306 shows the output voltage V_{OUT} when the light intensity striking the sensor pixel is relatively high. The relatively high intensity light striking the sensor pixel produces more photocurrent than the relatively low intensity. As a result, when the switch opens at time 310, the charge on the capacitor integrates more quickly, and the output voltage V_{OUT} drops more quickly. For the relatively high light intensity, the capacitor reaches saturation at time 312, after which the output voltage V_{OUT} remains at a minimum value V_{MIN}. When saturation occurs, the image processing unit returns a maximum light level for the saturated pixel. In practice, saturation is undesirable because high-intensity detail is washed out in the image; all pixels having an intensity greater than a saturation intensity all take on the minimum voltage V_{MIN}.

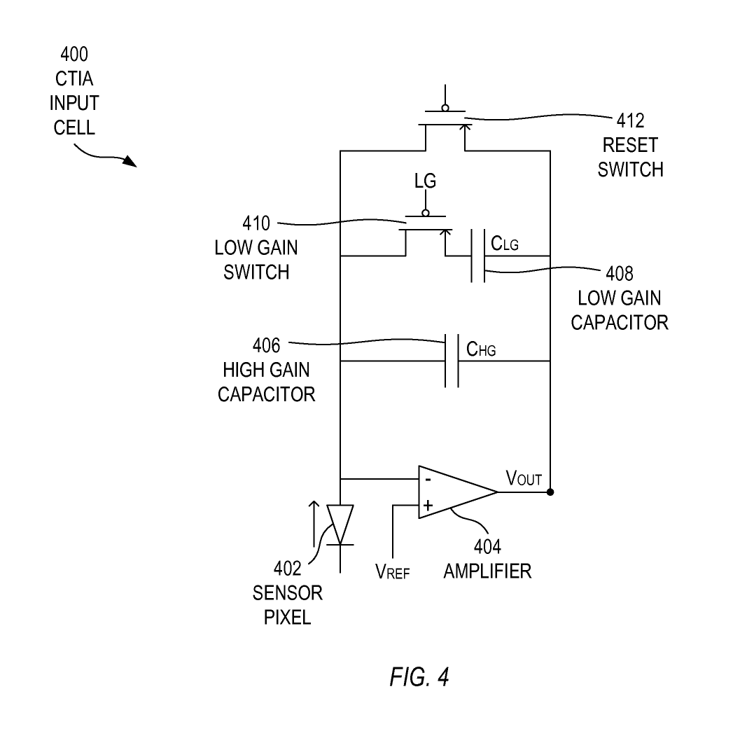

FIG. 4 is an electrical schematic drawing of an example of a CTIA input cell 400, in which a summed capacitance can be varied manually. The different summed capacitance values can accommodate both a low gain configuration, corresponding to a relatively high light intensity and a relatively high capacitance value, and a high gain configuration, corresponding to a relatively low light intensity and a relatively low capacitance value. The configuration of FIG. 4 is but one example; other configurations can also be used.

A sensor pixel 402 produces photocurrent in response to light incident thereon. The sensor pixel 402 output is electrically coupled to a first input to an amplifier 404, a first side of a high gain capacitor 406 having capacitance C_{HG}, a first side of a low gain switch 410, and a first side of a reset switch 412. The amplifier 404 has a constant voltage V_{REF} as its second input, and a variable voltage V_{OUT} as its output. The amplifier output is electrically coupled to the second side of the high gain capacitor 406, to a first side of a low gain capacitor 408 having capacitance C_{LG} where C_{LG} can be greater than C_{HG}, and to a second side of the reset switch 412. The second side of the low gain switch 410 is electrically coupled to the second side of the low gain capacitor 408. The ROIC periodically opens the reset switch 412 to start each video frame, and closes the reset switch 412 briefly to end each video frame.

The configuration of FIG. 4 can be referred to as a conventional global dual gain input cell. In this configuration, the ROIC actively, and manually, switches between high gain and low gain by opening or closing the low gain switch 410. When the gain is high, the low gain switch 410 is open, and charge integrates on only the high gain capacitor 406. The ROIC actively changes the gain from high to low by closing the low gain switch 410, thereby connecting the low gain capacitor 408 in parallel with the high gain capacitor and summing their capacitances. When the gain is low, charge integrates on both the high gain capacitor 406 and the low gain capacitor 408.

In most cases, the ROIC switches between high gain and low gain for all pixels, together, and does so on a video frame-by-frame basis. For a particular frame, the ROIC sets all the pixels to high gain, or all the pixels to low gain. The ROIC typically does not switch gains during a frame, and typically only switches gain between frames.

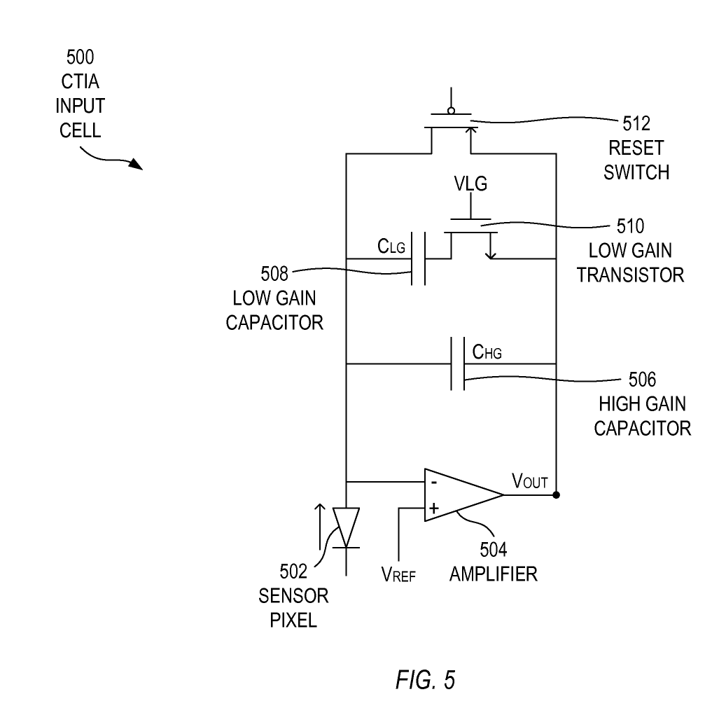

FIG. 5 is an electrical schematic drawing of an example of a CTIA input cell 500, in which a summed capacitance can be varied automatically. This configuration, in which the switching is automatic, improves over the configuration of FIG. 4, in which the switching is performed manually. The different summed capacitance values can accommodate both a low gain configuration, corresponding to a relatively high light intensity and a relatively high capacitance value, and a high gain configuration, corresponding to a relatively low light intensity and a relatively low capacitance value. The configuration of FIG. 5 is but one example; other configurations can also be used.

The sensor pixel 502, amplifier 504, high gain capacitor 506, and reset switch 512 are similar in structure and function to similarly numbered elements 4xx in FIG. 4. Compared with FIG. 4, the configuration of FIG. 5 replaces the low gain switch 410 with a low gain transistor 510, and moves the low gain capacitor to the opposite side of the switch/transistor. Low gain transistor 510 can be an NFET element.

Low gain transistor 510 functions as an open circuit for output voltages V_{OUT} greater than a threshold voltage below VLG. Low gain transistor 510 functions as a conductor for output voltages V_{OUT} less than the threshold voltage below VLG. During the initial portion of a frame, the output voltage is relatively high, the low gain transistor 510 remains open, the low gain capacitor 508 is removed from the circuit, and the charge integrates on the high gain capacitor 506. If the output voltages V_{OUT} decreases to the threshold voltage below VLG, the low gain transistor 510 inserts the low gain capacitor 508 into the circuit, and for the remainder of the frame, any further charge integrates on both the high gain capacitor 506 and the low gain capacitor 508.

Potential advantages to the automatic switching in of the low gain transistor 510 include allowing for per pixel dual gain, and keeping dual gain always active (as opposed to selecting either a high gain or a low gain at the beginning of a frame).

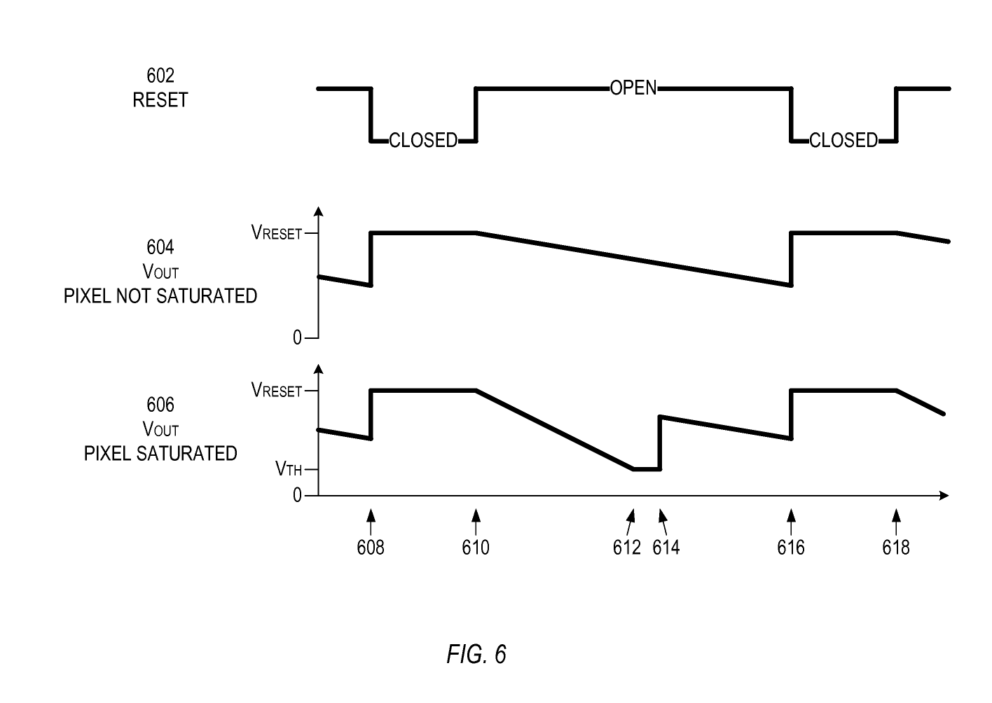

FIG. 6 includes plots of examples of a reset signal 602 and output voltages for the CTIA input cell of FIG. 5, for a particular sensor pixel. The reset switch closes at time 608, opens at time 610, closes at time 616, and opens at time 618. At time 612, the output voltage V_{OUT} falls to a threshold voltage V_{TH} below VLG, thereby triggering the low gain transistor (510; FIG. 5) to insert the low gain capacitor (508; FIG. 5). Just before time 614, the high gain voltage is sampled. At time 614, the CTIA input cell is switched to a low gain configuration, where the total integrating capacitance is increased, thereby reducing the slope of the curve 606 between time 614 and the end of the frame at time 616. The low gain voltage is sampled just before time 616. Both the high gain voltage and the low gain voltage are read for each pixel.

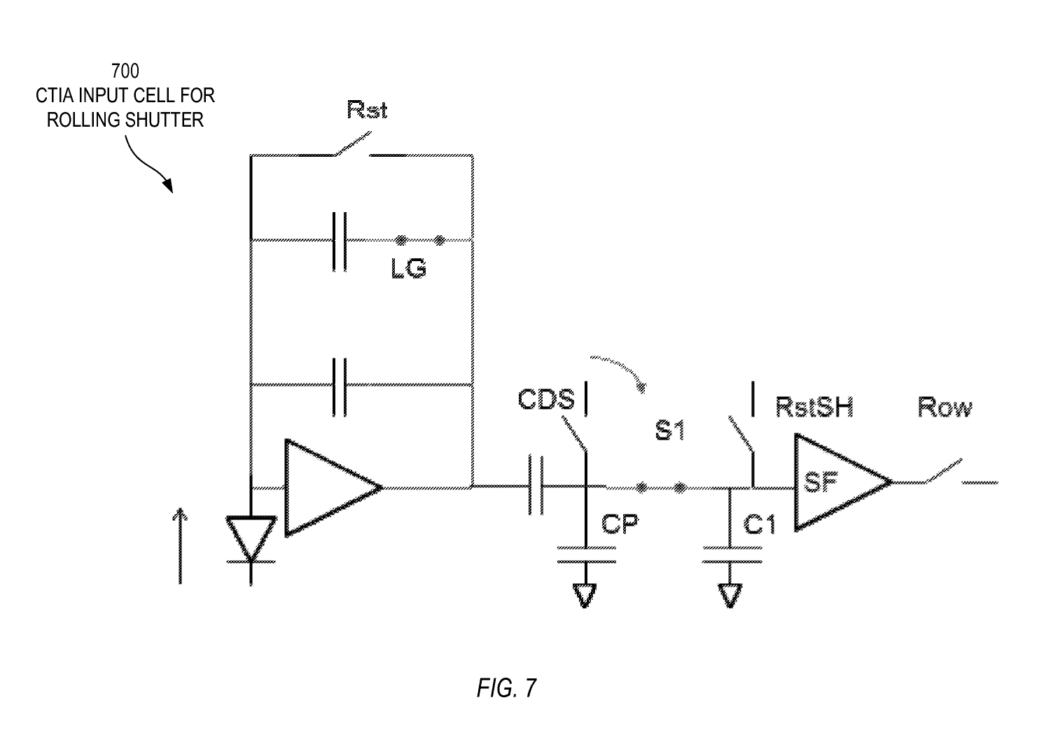

The circuits shown in FIGS. 2, 4, and 5 have been simplified for clarity. In practice, the configuration of the image capture device can dictate the configuration of the CTIA input cell circuitry. Four circuitry examples are shown in FIGS. 7-10, for four device configurations; other circuits and configurations are also possible.

FIG. 7 is an electrical schematic drawing of an example of a CTIA input cell 700, used with a rolling shutter configuration for the image capture device.

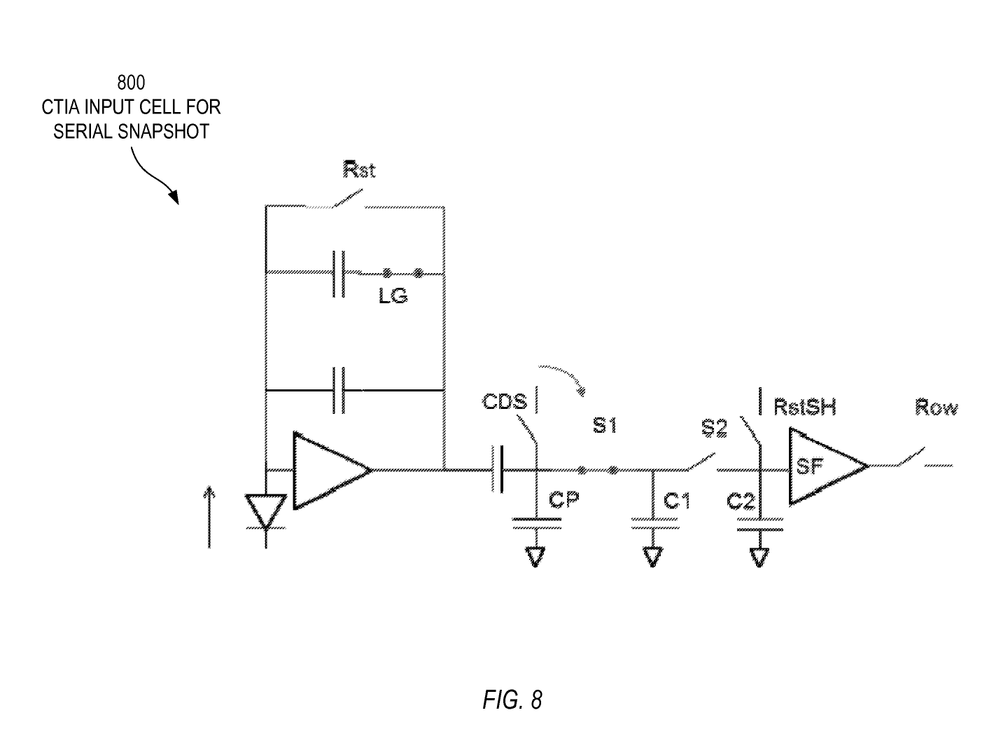

FIG. 8 is an electrical schematic drawing of an example of a CTIA input cell 800, used with a serial snapshot configuration for the image capture device.

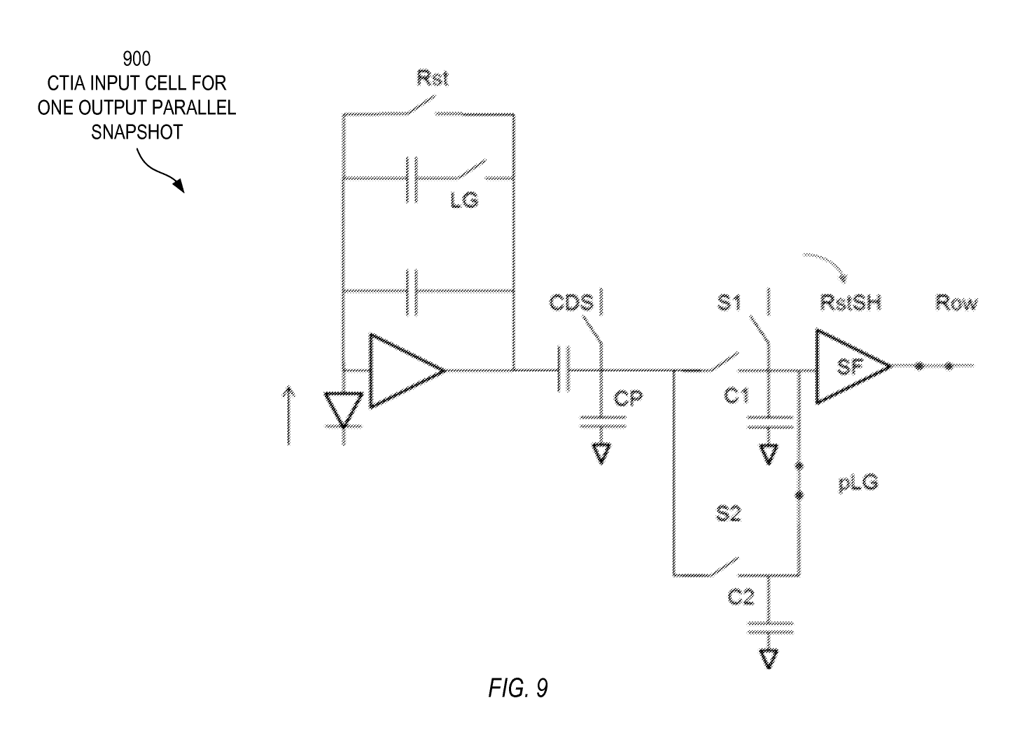

FIG. 9 is an electrical schematic drawing of an example of a CTIA input cell 900, used with a one output parallel snapshot configuration for the image capture device.

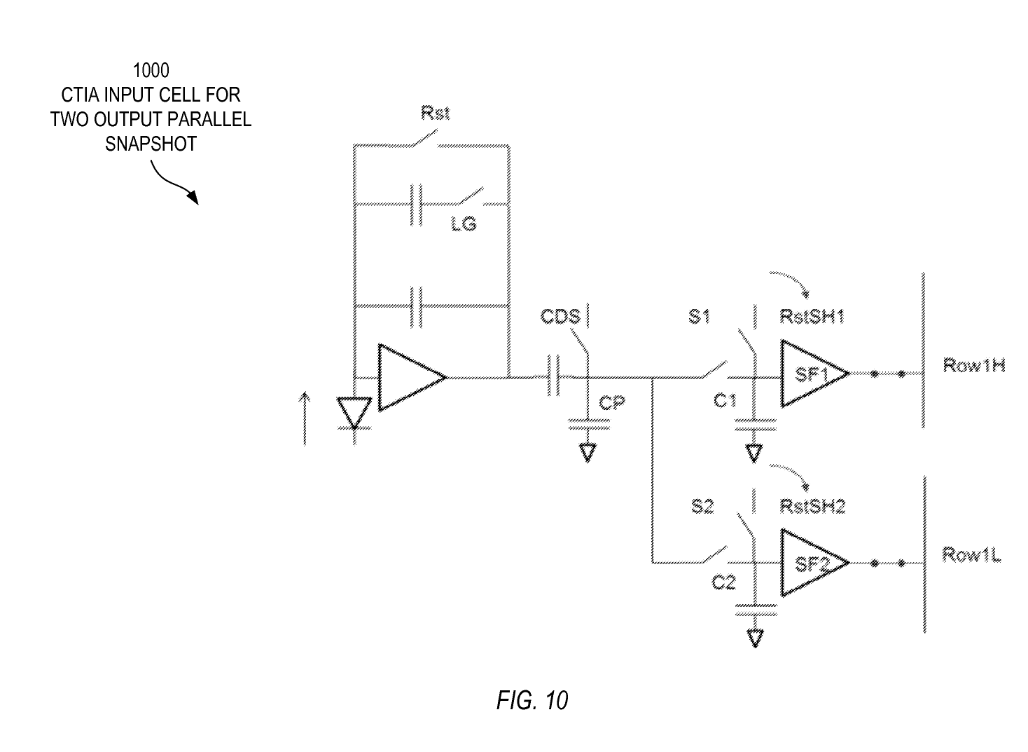

FIG. 10 is an electrical schematic drawing of an example of a CTIA input cell 1000, used with a two output parallel snapshot configuration for the image capture device.

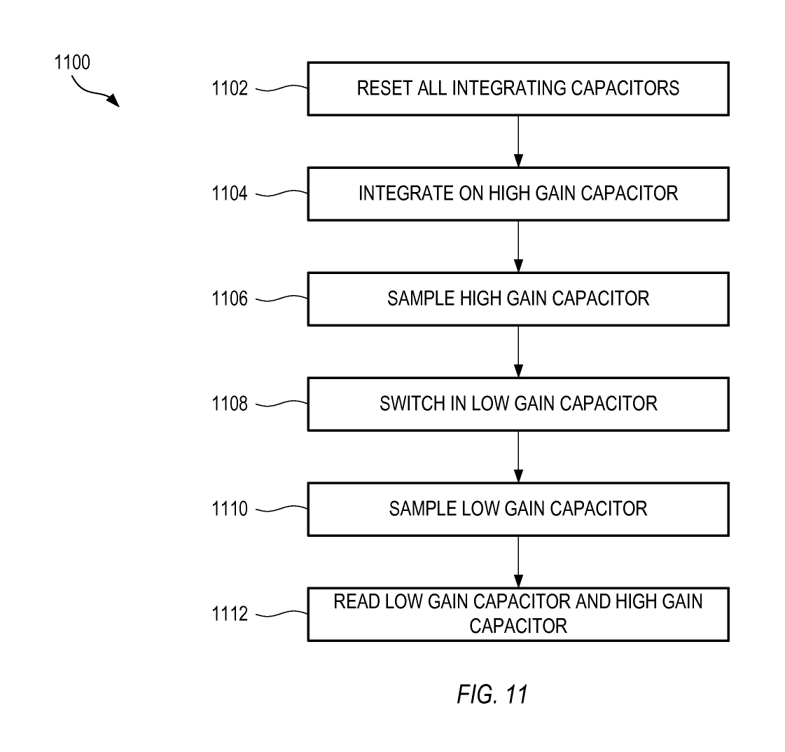

FIG. 11 is a flow chart of an example of a method of operation 1100 for a CTIA input cell. Such a method 1100 can be executed on the CTIA input cell 500 of FIG. 5, or on other suitable CTIA input cells. The method 1100 is but one example of a method of operation; other suitable methods of operation can also be used.

At 1102, method 1100 resets all the integrating capacitors in the CTIA input cell. Examples of such capacitors can include high gain capacitor 506 (FIG. 5) and low gain capacitor 508 (FIG. 5). At 1104, a high gain capacitor, such as 506 (FIG. 5), integrates charge arising from photocurrent. At 1106, method 1100 samples the high gain capacitor. If the high gain capacitor is saturated, then a low gain capacitor can be automatically activated at saturation, which can absorb excess charge. At 1108, method 1100 switches in the low gain capacitor. If the low gain capacitor is saturated, then the low gain capacitor has already been activated. The low gain capacitor can be switched in, regardless of whether the high gain capacitor is saturated. At 1110, method 1100 samples the low gain capacitor. At 1112, method 1100 reads the low gain capacitor and the high gain capacitor.

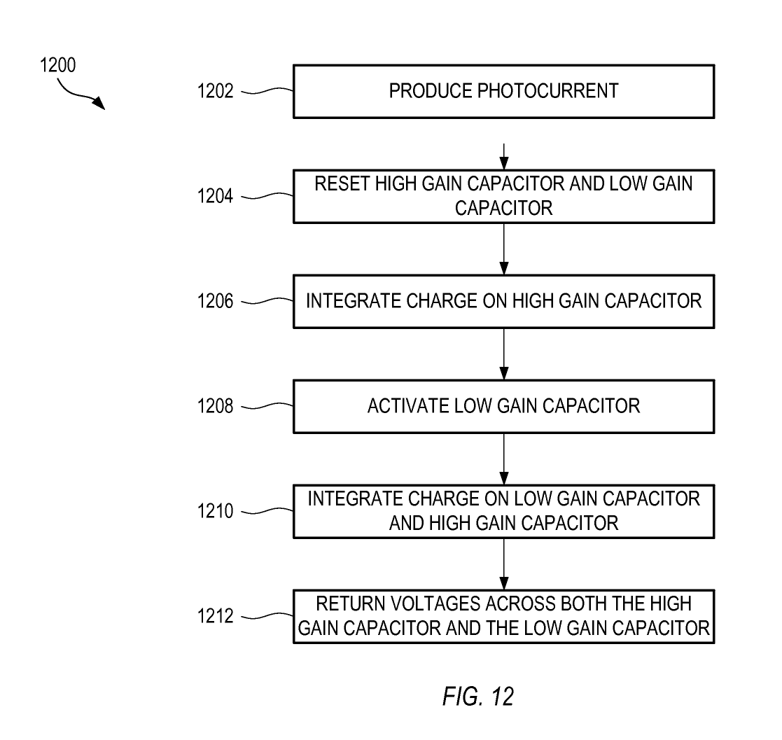

FIG. 12 is a flow chart of another example of a method 1200 of operating a CTIA input cell, such as CTIA input cell 500 of FIG. 5. This flow chart assumes that there is saturation at the high gain capacitor, and omits the decision steps.

At 1202, method 1200 produces photocurrent from a sensor pixel having light incident thereon. At 1204, method 1200 resets a high gain capacitor and a low gain capacitor to respective specified reset voltages at a beginning of a video frame. In some examples, the specified reset voltages are the same; in other examples, they can differ. At 1206, method 1200 integrates charge arising from the photocurrent on the high gain capacitor. The method 1200 senses a voltage across the high gain capacitor. If the sensed voltage has dropped to a specified threshold voltage, then at 1208 method 1200 automatically activates the low gain capacitor to be electrically coupled in parallel with the high gain capacitor. Method 1200 switches in the low gain capacitor. Switching in the low gain capacitor allows the voltage on the sum of the capacitors to be read. Until the low gain capacitor is switched in, the voltage at the output of the CTIA is just that due to the high gain capacitor. At 1210, method 1200 integrates the charge arising from the photocurrent on both the low gain capacitor and the high gain capacitor. Method 1200 samples a second voltage across both the low gain capacitor and the high gain capacitor. At 1212, method 1200 returns the first and second voltages at an end of the video frame. The first and second voltages correspond to a light intensity incident on the sensor pixel integrated over the video frame.

The method 1200 of FIG. 12 is configured to sense one frame of video. The method can be repeated as needed to sense a sequence of video frames.

In an alternate configuration, the CTIA input cell can include three capacitors, rather than two. When a first of the three capacitors reaches saturation, a first transistor switches in a second capacitor in parallel to the first capacitor. When the second of the three capacitors reaches saturation, a second transistor switches in a third capacitor in parallel to the first and second capacitors. Such a configuration can automatically switch among three gain levels, with the gain level for each pixel being automatically switched independent of the other pixels.

In further alternate configurations, the CTIA input cell can include four, five, six, or more than six capacitors. These alternate configurations can also include three, four, five, or more than five transistors to switch in the respective capacitors as needed.

It will be understood that the absolute sign of the voltages presented herein is arbitrary. For instance, the plus and minus inputs on the amplifiers 204, 404, 504 may be switched, thereby switching positive voltages to negative voltages, and vice versa. If the absolute signs of the voltages are switched from those discussed above, all references of “greater than” and “less than”, “above” and “below, and the like, should be switched as well.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. A charge transimpedance amplifier (CTIA) input cell configured to receive photocurrent and produce an output voltage corresponding to an integrated charge from the photocurrent, the CTIA input cell comprising:
a reset switch electrically coupled in parallel to the high gain capacitor, the reset switch being configured to periodically set a voltage to a specified reset level to mark a beginning of a video frame;
a high gain capacitor electrically coupled in parallel to the reset switch, the high gain capacitor having a voltage thereacross set to the specified reset level at the beginning of the video frame, the high gain capacitor configured to integrate charge arising from the photocurrent, wherein as charge integrates on the high gain capacitor, the voltage across the high gain capacitor decreases, the high gain capacitor having a first side electrically coupled to the photocurrent;
a low gain capacitor having a first side electrically coupled to the photocurrent and the first side of the high gain capacitor;
a low gain transistor having a first side electrically coupled to a second side of the high gain capacitor, and having a second side electrically coupled to a second side of the low gain capacitor, the low gain transistor being configured to be electrically insulating when the voltage across the high gain capacitor exceeds a specified threshold and be electrically conducting when the voltage across the high gain capacitor is below the specified threshold;
an amplifier having a first input electrically coupled to the photocurrent, to a first side of the high gain capacitor, and to a first side of the low gain capacitor, the amplifier having a second input electrically coupled to a constant voltage, the amplifier having an output electrically coupled to the second side of the high gain capacitor and the first side of the low gain transistor;
wherein the amplifier output at an end of the video frame forms the output voltage.

2. The CTIA input cell of claim 1, further comprising:
a sensor pixel configured to produce the photocurrent in response to light incident thereon;
wherein the sensor pixel is electrically coupled to a first side of the high gain capacitor and a first side of the low gain capacitor.

3. The CTIA input cell of claim 1, further comprising a read out integrated circuit (ROIC) configured to assemble and correlate output voltages from a plurality of CTIA input cells, each CTIA input cell corresponding to a sensor pixel in an image sensor.

4. The CTIA input cell of claim 3, further comprising an image processing unit configured to convert the assembled and correlated output voltages from the ROIC into an electronic representation of an image incident on the image sensor.

5. A charge transimpedance amplifier (CTIA) input cell configured to receive photocurrent and produce an output voltage corresponding to an integrated charge from the photocurrent, the CTIA input cell comprising:
a high gain capacitor configured to integrate charge arising from the photocurrent;
a low gain capacitor; and
a low gain transistor, configured to automatically electrically couple the low gain capacitor in parallel to the high gain capacitor when a voltage across the high gain capacitor reaches a specified threshold.

6. The CTIA input cell of claim 5, wherein as charge integrates on the high gain capacitor, the voltage across the high gain capacitor decreases.

7. The CTIA input cell of claim 6,
wherein the low gain transistor is configured to be electrically insulating when the voltage across the high gain capacitor exceeds the specified threshold and be electrically conducting when the voltage across the high gain capacitor is below the specified threshold.

8. The CTIA input cell of claim 5, wherein the low gain capacitor is electrically disposed between the low gain transistor a source of the photocurrent.

9. The CTIA input cell of claim 5, further comprising:
a sensor pixel configured to produce the photocurrent in response to light incident thereon;
wherein the sensor pixel is electrically coupled to a first side of the high gain capacitor and a first side of the low gain capacitor.

10. The CTIA input cell of claim 5, further comprising:
an amplifier;
wherein the amplifier has a first input electrically coupled to the photocurrent, to a first side of the high gain capacitor, and to a first side of the low gain capacitor;
wherein the amplifier has a second input electrically coupled to a constant voltage; and
wherein the amplifier produces the output voltage as its output, the output being electrically coupled to a second side of the high gain capacitor and a first side of the low gain transistor; and
wherein a second side of the low gain transistor is electrically coupled to a second side of the low gain capacitor.

11. The CTIA input cell of claim 5, further comprising:
a reset switch electrically coupled in parallel to the high gain capacitor, the reset switch being configured to periodically set a voltage across the high gain capacitor and the low gain capacitor to a specified reset level.

12. The CTIA input cell of claim 5, further comprising:
a reset switch electrically coupled in parallel to the high gain capacitor, the reset switch being configured to periodically set a voltage across the high gain capacitor and the low gain capacitor to a specified reset level; and
an amplifier, the amplifier having a first input electrically coupled to the photocurrent, to a first side of the high gain capacitor, and to a first side of the low gain capacitor, the amplifier having a second input electrically coupled to a constant voltage, the amplifier having an output electrically coupled to a second side of the high gain capacitor and a first side of the low gain transistor;
wherein the amplifier output forms the output voltage.

13. The CTIA input cell of claim 12, further comprising a read out integrated circuit (ROIC) configured to assemble and correlate output voltages from a plurality of CTIA input cells, each CTIA input cell corresponding to a sensor pixel in an image sensor.

14. The CTIA input cell of claim 13, further comprising an image processing unit configured to convert the assembled and correlated output voltages from the ROIC into an electronic representation of an image incident on the image sensor.

15. A method of operating a CTIA input cell, comprising:
producing photocurrent from a sensor pixel having light incident thereon;
resetting a high gain capacitor and a low gain capacitor to respective specified reset voltages at a beginning of a video frame;
integrating charge arising from the photocurrent on the high gain capacitor;
sensing a voltage across the high gain capacitor;
if the sensed voltage has dropped to a specified threshold voltage, then automatically activating the low gain capacitor to be electrically coupled in parallel with the high gain capacitor;
sampling a first voltage across the high gain capacitor;
switching in the low gain capacitor;
integrating the charge arising from the photocurrent on both the low gain capacitor and the high gain capacitor;
sampling a second voltage across both the low gain capacitor and the high gain capacitor; and
returning the first and second voltages at an end of the video frame, the first and second voltages corresponding to a light intensity incident on the sensor pixel integrated over the video frame.

16. The method of claim 15, further comprising, after returning the voltage:
resetting the high gain capacitor and the low gain capacitor to the respective specified reset voltages at a beginning of a second video frame;
integrating charge arising from the photocurrent on the high gain capacitor;
sensing a voltage across the high gain capacitor;
if the sensed voltage has dropped to the specified threshold voltage, then automatically activating the low gain capacitor to be electrically coupled in parallel with the high gain capacitor;
sampling a third voltage across the high gain capacitor;
switching in the low gain capacitor;
integrating the charge arising from the photocurrent on both the low gain capacitor and the high gain capacitor;
sampling a fourth voltage across both the low gain capacitor and the high gain capacitor; and
returning the third and fourth voltages at an end of the second video frame, the third and fourth voltages corresponding to a light intensity incident on the sensor pixel integrated over the video frame.

17. The method of claim 15, further comprising:
assembling and correlating returned voltages from a plurality of CTIA input cells, each CTIA input cell corresponding to a sensor pixel in an image sensor.

18. The method of claim 17, further comprising:
converting the assembled and correlated returned voltages into an electronic representation of an image incident on the image sensor.
